(19) United States
(12) Patent Application Publication
(10) Pub. No.: US 2006/0033486 A1
(43) Pub. Date: Feb. 16, 2006

(54) Transient voltage detecting circuit

(75) Inventor: Kuo-Yu Chou, HsinChu (TW)

Correspondence Address: TROXELL LAW OFFICE PLLC;SUITE 1404, 5205 LEESBURG PIKE, FALLS CHURCH, VA, 22041, US

(73) Assignee: Novatek Microelectronic Co.

(21) Appl. No.: 10/969,999

(22) Filed: Oct. 22, 2004

(30) Foreign Application Priority Data
Aug. 13, 2004 (TW) 093124300

(51) Int. Cl. G01R 19/00

(52) U.S. Cl. 324/102

(57) ABSTRACT

The invention provides a circuit for detecting a transient voltage for an electronic system having a power supply port and a ground port. The circuit includes a capacitor, a rectifying device, a pre-set resistance device and a detecting device. According to one preferred embodiment of the invention, the detecting device has an input coupled to a second terminal of the capacitor. Once the transient voltage occurs at the power supply port, and when the voltage at the second terminal of the capacitor is higher than a threshold voltage, the detecting device outputs an output voltage for representing occurrence of the transient voltage.

### BACKGROUND OF THE INVENTION

1. Field of the Invention

This invention relates to a transient voltage detecting circuit for detecting a transient voltage for an electronic system. Specifically, each component in the transient voltage detecting circuit according to this invention doesn't relate to nor refer to the power ports of the electronic system. Therefore, once a transient voltage occurs, each component in the transient voltage detecting circuit according to this invention still keeps its original electrical characteristics and then detects the transient voltages quickly and accurately.

2. Description of the Prior Art

General electronic systems, especially integrated circuits, all take self-protections against undesired transient voltages, such as surges, glitches, overvoltages, etc., to prevent the above transient voltages from causing the systems mal-function and even crash or damages to the components.

The self-protections against undesired transient voltages in electronic systems aimed for detecting the transient voltages quickly and accurately. Please refer to the patent U.S. Pat. No. 5,999,392 for the prior arts about transient voltage detection. The patent U.S. Pat. No. 5,999,392 discloses an automatic resetting circuit having the function for detecting transient voltage variations. The circuit is used to detect unusual voltage variations between power supply port and ground port of the electronic systems, and then reset the electronic systems.

However, the prior arts about transient voltage detection still use components relating to or referring to the power ports of the electronic system, such as NAND gates, NOR gates, and NOT gates, etc. Accordingly, once a transient voltage occurs, the components relating to or referring to the power ports of the electronic system may not keep their original electrical characteristics. Hence, the accuracy of the transient voltage detecting circuits that use components relating to or referring to the power ports of the electronic system is worrisome.

Accordingly, one main purpose of this invention is to provide a transient voltage detecting circuit. Specifically, each component in the transient voltage detecting circuit according to this invention doesn't relate to nor refer to the power ports of the electronic system.

### SUMMARY OF THE INVENTION

The main objective of the invention is to provide a transient voltage detecting circuit for detecting a transient voltage for an electronic system. Specifically, each component in the transient voltage detecting circuit according to this invention doesn't relate to nor refer to the power ports of the electronic system. Therefore, once a transient voltage occurs, each component in the transient voltage detecting circuit according to this invention still keeps its original electrical characteristics and then detects the transient voltages quickly and accurately.

A transient voltage detecting circuit, according to the first preferred embodiment of the invention, includes a capacitor, a rectifying device, a pre-set resistance device, and a detecting device. The capacitor has a first terminal, coupled to the ground port, and a second terminal. The rectifying device has an operating forward orientation. The second terminal of the capacitor is coupled through the rectifying device to the power supply port, and the operating forward orientation of the rectifying device orients toward the capacitor such that when the electronic system operates normally, a voltage at the second terminal of the capacitor relates to the power supply port. The detecting device has an input coupled to the second terminal of the capacitor and a threshold voltage. Once a positive transient voltage occurs at the power supply port, and when the voltage at the second terminal of the capacitor is higher than the threshold voltage, the detecting device outputs an output voltage for representing the occurrence of said transient voltage. The pre-set resistance device, coupled in parallel with the capacitor, is used to pre-set an operating voltage for the circuit to make the circuit operate normally.

A transient voltage detecting circuit, according to the second preferred embodiment of the invention, includes a capacitor, a rectifying device, a pre-set resistance device, and a detecting device. The capacitor has a first terminal, coupled to the ground port, and a second terminal. The rectifying device has an operating forward orientation. The second terminal of the capacitor is coupled through the rectifying device to the power supply port, and the operating forward orientation of the rectifying device orients toward the power supply port such that when the electronic system operates normally, a voltage at the second terminal of the capacitor relates to the power supply port. The detecting device has an input coupled to the second terminal of the capacitor and a threshold voltage. Once a negative transient voltage occurs at the power supply port, and when the voltage at the second terminal of the capacitor is higher than the threshold voltage, the detecting device outputs an output voltage for representing the occurrence of said transient voltage. The pre-set resistance device, coupled in parallel with the rectifying device, is used to pre-set an operating voltage for the circuit to make the circuit operate normally.

A transient voltage detecting circuit, according to the third preferred embodiment of the invention, includes a capacitor, a rectifying device, a pre-set resistance device, and a detecting device. The capacitor has a first terminal, coupled to the power supply port, and a second terminal. The rectifying device has an operating forward orientation. The second terminal of the capacitor is coupled through the rectifying device to the ground port, and the operating forward orientation of the rectifying device orients toward the capacitor such that when the electronic system operates normally, a voltage at the second terminal of the capacitor relates to the ground port. The detecting device has an input coupled to the second terminal of the capacitor and a threshold voltage. Once a positive transient voltage occurs at the ground port, and when the voltage at the second terminal of the capacitor is higher than the threshold voltage, the detecting device outputs an output voltage for representing the occurrence of said transient voltage. The pre-set resistance device, coupled in parallel with the rectifying device, is used to pre-set an operating voltage for the circuit to make the circuit operate normally.

A transient voltage detecting circuit, according to the fourth preferred embodiment of the invention, includes a capacitor, a rectifying device, a pre-set resistance device, and a detecting device. The capacitor has a first terminal, coupled to the power supply port, and a second terminal. The rectifying device has an operating forward orientation. The second terminal of the capacitor is coupled through the rectifying device to the ground port, and the operating forward orientation of the rectifying device orients toward the ground port such that when the electronic system operates normally, a voltage at the second terminal of the capacitor relates to the ground port. The detecting device has an input coupled to the second terminal of the capacitor and a threshold voltage. Once a negative transient voltage occurs at the ground port, and when the voltage at the second terminal of the capacitor is higher than the threshold voltage, the detecting device outputs an output voltage for representing the occurrence of said transient voltage. The pre-set resistance device, coupled in parallel with the capacitor, is used to pre-set an operating voltage for the circuit to make the circuit operate normally.

The advantage and spirit of the invention may be understood by the following recitations together with the appended drawings.

### BRIEF DESCRIPTION OF THE APPENDED DRAWINGS

FIG. 1 is the transient voltage detecting circuit 1, according to the first preferred embodiment of the invention, applied to detecting the occurrence of a positive transient voltage at the power supply port VCC in an electronic system;

FIG. 2 is the transient voltage detecting circuit 1, according to the second preferred embodiment of the invention, applied to detecting the occurrence of a negative transient voltage at the power supply port VCC in an electronic system;

FIG. 3 is the transient voltage detecting circuit 1, according to the third preferred embodiment of the invention, applied to detecting the occurrence of a positive transient voltage at the ground port GND in an electronic system; and

FIG. 4 is the transient voltage detecting circuit 1, according to the fourth preferred embodiment of the invention, applied to detecting the occurrence of a negative transient voltage at the ground port GND in an electronic system.

### DETAILED DESCRIPTION OF THE INVENTION

This invention provides a transient voltage detecting circuit for detection of a transient voltage for an electronic system. The electronic system is a typical one, for example, an integrated circuit, and has a power supply port and a ground port. The transient voltage detecting circuit according to this invention applies to detections of positive/negative transient voltages at power supply port and ground port for a general electronic system (integrated circuit.) Several preferred embodiments of this invention described below can point out the spirits and characteristics of this invention.

### The First Preferred Embodiment

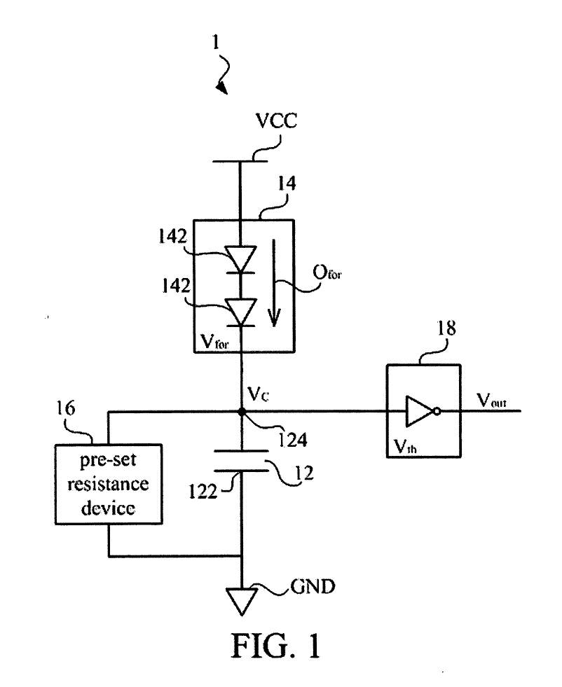

Please refer to FIG. 1, which discloses the basic architecture of the transient voltage detecting circuit 1, according to the first preferred embodiment of the invention. The integrated circuit 1 applies to detecting the occurrence of a positive transient voltage at the power supply port VCC in a general electronic system (not drawn in the figure.)

As shown in FIG. 1, the transient voltage detecting circuit 1 includes a capacitor 12, a rectifying device 14, a pre-set resistance device 16, and a detecting device 18.

The capacitor 12 has a first terminal 122, coupled to the ground port GND of the electronic system, and a second terminal 124, coupled in serial through the rectifying device 14 to the power supply port VCC.

The rectifying device 14 has an operating forward orientation O_{for} and a characteristic voltage V_{for}. The operating forward orientation O_{for} of the rectifying device 14 orients toward the capacitor 12 such that when the electronic system operates normally, a voltage V_{c} at the second terminal 124 of the capacitor 12 equals (VCC−V_{for.})

The detecting device 18 has an input coupled to the second terminal 124 of the capacitor 12 and a threshold voltage Vₜₕ.

Once a positive transient voltage, which makes the voltage of the power supply port increases ΔV and the voltage V_{c} at the second terminal 124 of the capacitor 12 equals (VCC−V_{for}+ΔV), occurs at the power supply port VCC, and when the voltage V_{c} at the second terminal 124 of the capacitor 12 is higher than the threshold voltage Vₜₕ, the detecting device 18 outputs an output voltage Vₒᵤₜ for representing the occurrence of said transient voltage. The output voltage Vₒᵤₜ can be used to trigger a resetting device (not drawn in the figure) for the electronic system to protect the electronic system from damages caused by the positive transient voltage.

Also as shown in FIG. 1, the pre-set resistance device 16, coupled in parallel with the capacitor 12, is used to conduct the rectifying device 14 to make said circuit 1 operate normally. Without the pre-set resistance device 16, the voltage V_{c} at the second terminal 124 may be higher than (VCC−V_{for}), and the detection function of the whole circuit fails.

In an embodiment as shown in FIG. 1, the rectifying device 14 consists of a plurality of diodes coupled in serial. In another embodiment, the rectifying device 14 consists of a plurality of MOS transistors coupled in serial.

In an embodiment as shown in FIG. 1, the pre-set resistance device 16 is a programmable resistor. In another embodiment, the pre-set resistance device 16 is a MOS transistor. It's necessary to declare that the resistance of the pre-set resistance device 16 should be large enough such that the capacitor 12 with voltage change cannot discharge rapidly when transient voltages occur. Generally speaking, the resistance of the pre-set resistance device 16 might be higher than several K−Ω, and even as high as several M−Ω.

In an embodiment as shown in FIG. 1, the detecting device 18 is an inverter. In another embodiment, the detecting device 18 is a comparator or other detecting components that don't relate to nor refer to the power ports of the electronic system.

### The Second Preferred Embodiment

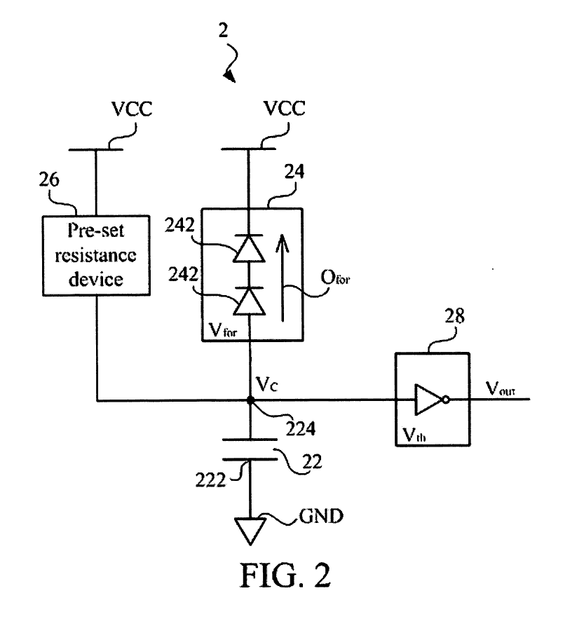

Please refer to FIG. 2, which discloses the basic architecture of the transient voltage detecting circuit 2, according to the second preferred embodiment of the invention. The integrated circuit 2 applies to detecting the occurrence of a negative transient voltage at the power supply port VCC in a general electronic system (not drawn in the figure.)

As shown in FIG. 2, the transient voltage detecting circuit 2 includes a capacitor 22, a rectifying device 24, a pre-set resistance device 26, and a detecting device 28.

The capacitor 22 has a first terminal 222, coupled to the ground port GND of the electronic system, and a second terminal 224, coupled in serial through the rectifying device 24 to the power supply port VCC.

The rectifying device 24 has an operating forward orientation O_{for} and a characteristic voltage V_{for}. The operating forward orientation O_{for} of the rectifying device 24 orients toward the power supply port VCC such that when the electronic system operates normally, a voltage V_{c} at the second terminal 224 of the capacitor 22 equals VCC.

The detecting device 28 has an input coupled to the second terminal 224 of the capacitor 22 and a threshold voltage Vₜₕ.

Once a negative transient voltage, which makes the voltage of the power supply port decreases (V_{for}+ΔV) and the voltage V_{c} at the second terminal 224 of the capacitor 22 equals (VCC−ΔV), occurs at the power supply port VCC, and when the voltage V_{c} at the second terminal 224 of the capacitor 22 is lower than the threshold voltage Vₜₕ, the detecting device 28 outputs an output voltage Vₒᵤₜ for representing the occurrence of said transient voltage. The output voltage Vₒᵤₜ can be used to trigger a resetting device (not drawn in the figure) for the electronic system to protect the electronic system from damages caused by the negative transient voltage.

Also as shown in FIG. 2, the pre-set resistance device 26, coupled in parallel with the capacitor 22, is used to preset the voltage V_{c} at the second terminal 224 as VCC to make said circuit 2 operate normally.

In an embodiment as shown in FIG. 2, the rectifying device 24 consists of a plurality of diodes coupled in serial. In another embodiment, the rectifying device 24 consists of a plurality of MOS transistors coupled in serial.

In an embodiment as shown in FIG. 2, the pre-set resistance device 26 is a programmable resistor. In another embodiment, the pre-set resistance device 26 is a MOS transistor. It's necessary to declare that the resistance of the pre-set resistance device 26 should be large enough such that the capacitor 22 with voltage change cannot discharge rapidly when transient voltages occur. Generally speaking, the resistance of the pre-set resistance device 26 might be higher than several K−Ω, and even as high as several M−Ω.

In an embodiment as shown in FIG. 2, the detecting device 28 is an inverter. In another embodiment, the detecting device 28 is a comparator or other detecting components that don't relate to nor refer to the power ports of the electronic system.

### The Third Preferred Embodiment

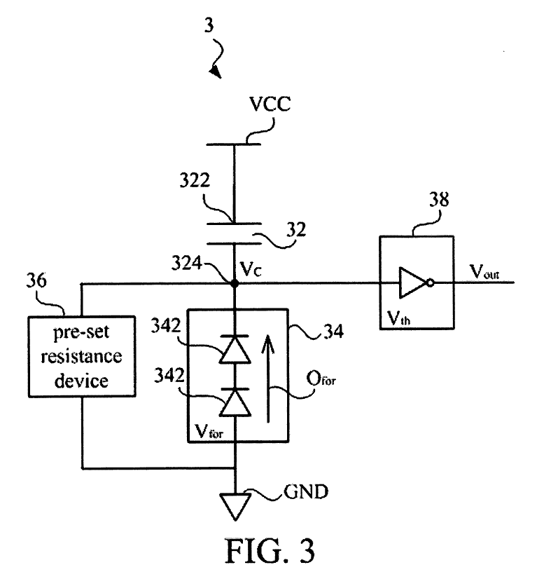

Please refer to FIG. 3, which discloses the basic architecture of the transient voltage detecting circuit 3, according to the third preferred embodiment of the invention. The integrated circuit 3 applies to detecting the occurrence of a positive transient voltage at the ground port GND in a general electronic system (not drawn in the figure.)

As shown in FIG. 3, the transient voltage detecting circuit 3 includes a capacitor 32, a rectifying device 34, a pre-set resistance device 36, and a detecting device 38.

The capacitor 32 has a first terminal 322, coupled to the power supply port VCC of the electronic system, and a second terminal 324, coupled in serial through the rectifying device 34 to the ground port GND.

The rectifying device 34 has an operating forward orientation O_{for} and a characteristic voltage V_{for}. The operating forward orientation O_{for} of the rectifying device 34 orients toward the capacitor 32 such that when the electronic system operates normally, a voltage V_{c} at the second terminal 324 of the capacitor 32 equals 0.

The detecting device 38 has an input coupled to the second terminal 324 of the capacitor 32 and a threshold voltage Vₜₕ.

Once a positive transient voltage, which makes the voltage of the power supply port increases (V_{for}+ΔV) and the voltage V_{c} at the second terminal 324 of the capacitor 32 equals ΔV, occurs at the ground port GND, and when the voltage V_{c} at the second terminal 324 of the capacitor 32 is higher than the threshold voltage Vₜₕ, the detecting device 38 outputs an output voltage Vₒᵤₜ for representing the occurrence of said transient voltage. The output voltage Vₒᵤₜ can be used to trigger a resetting device (not drawn in the figure) for the electronic system to protect the electronic system from damages caused by the positive transient voltage.

Also as shown in FIG. 3, the pre-set resistance device 36, coupled in parallel with the capacitor 32, is used to preset the voltage V_{c} at the second terminal 324 as zero (GND) to make said circuit 3 operate normally.

In an embodiment as shown in FIG. 3, the rectifying device 34 consists of a plurality of diodes coupled in serial. In another embodiment, the rectifying device 34 consists of a plurality of MOS transistors coupled in serial.

In an embodiment as shown in FIG. 3, the pre-set resistance device 36 is a programmable resistor. In another embodiment, the pre-set resistance device 36 is a MOS transistor. It's necessary to declare that the resistance of the pre-set resistance device 36 should be large enough such that the capacitor 32 with voltage change cannot discharge rapidly when transient voltages occur. Generally speaking, the resistance of the pre-set resistance device 36 might be higher than several K−Ω, and even as high as several M−Ω.

In an embodiment as shown in FIG. 3, the detecting device 38 is an inverter. In another embodiment, the detecting device 38 is a comparator or other detecting components that don't relate to nor refer to the power ports of the electronic system.

### The Fourth Preferred Embodiment

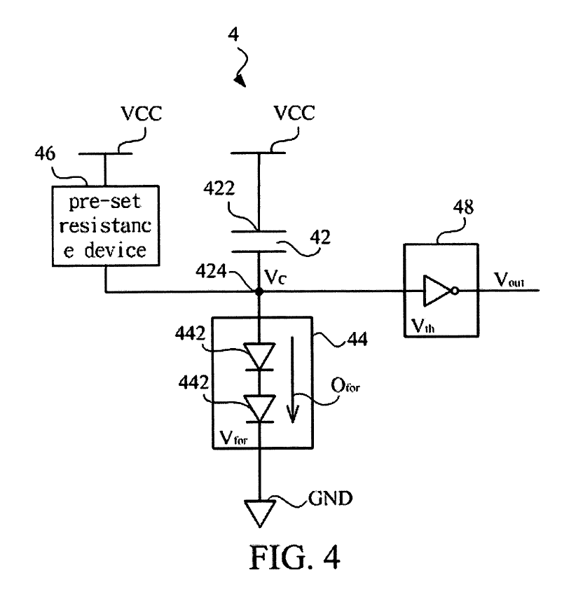

Please refer to FIG. 4, which discloses the basic architecture of the transient voltage detecting circuit 4, according to the fourth preferred embodiment of the invention. The integrated circuit 4 applies to detecting the occurrence of a negative transient voltage at the ground port GND in a general electronic system (not drawn in the figure.)

As shown in FIG. 4, the transient voltage detecting circuit 4 includes a capacitor 42, a rectifying device 44, a pre-set resistance device 46, and a detecting device 48.

The capacitor 42 has a first terminal 422, coupled to the power supply port VCC of the electronic system, and a second terminal 424, coupled in serial through the rectifying device 44 to the ground port GND.

The rectifying device 44 has an operating forward orientation O_{for} and a characteristic voltage V_{for}. The operating forward orientation O_{for} of the rectifying device 44 orients toward the ground port GND such that when the electronic system operates normally, a voltage V_{c} at the second terminal 424 of the capacitor 42 equals V_{for}.

The detecting device 48 has an input coupled to the second terminal 424 of the capacitor 42 and a threshold voltage Vₜₕ.

Once a negative transient voltage, which makes the voltage of the power supply port decreases ΔV and the voltage V_{c} at the second terminal 424 of the capacitor 42 equals (V_{for}−ΔV), occurs at the ground port GND, and when the voltage V_{c} at the second terminal 424 of the capacitor 42 is lower than the threshold voltage Vₜₕ, the detecting device 48 outputs an output voltage Vₒᵤₜ for representing the occurrence of said transient voltage. The output voltage Vₒᵤₜ can be used to trigger a resetting device (not drawn in the figure) for the electronic system to protect the electronic system from damages caused by the negative transient voltage.

Also as shown in FIG. 4, the pre-set resistance device 46, coupled in parallel with the capacitor 42, is used to preset the voltage V_{c} at the second terminal 424 as V_{for} to make said circuit 4 operate normally.

In an embodiment as shown in FIG. 4, the rectifying device 44 consists of a plurality of diodes coupled in serial. In another embodiment, the rectifying device 44 consists of a plurality of MOS transistors coupled in serial.

In an embodiment as shown in FIG. 4, the pre-set resistance device 46 is a programmable resistor. In another embodiment, the pre-set resistance device 46 is a MOS transistor. It's necessary to declare that the resistance of the pre-set resistance device 46 should be large enough such that the capacitor 42 with voltage change cannot discharge rapidly when transient voltages occur. Generally speaking, the resistance of the pre-set resistance device 46 might be higher than several K−Ω, and even as high as several M−Ω.

In an embodiment as shown in FIG. 4, the detecting device 48 is an inverter. In another embodiment, the detecting device 48 is a comparator or other detecting components that don't relate to nor refer to the power ports of the electronic system.

With the example and explanations above, the features and spirits of the invention will be hopefully well described. Those skilled in the art will readily observe that numerous modifications and alterations of the device may be made while retaining the teaching of the invention. Accordingly, the above disclosure should be construed as limited only by the metes and bounds of the appended claims.

What is claimed is:

1. A circuit for detecting a transient voltage for an electronic system having a power supply port and a ground port, said circuit comprising:
a capacitor having a first terminal, coupled to the ground port, and a second terminal;
a rectifying device having an operating forward orientation, the second terminal of the capacitor being coupled through the rectifying device to the power supply port, and the operating forward orientation of the rectifying device orienting toward the capacitor such that a voltage at the second terminal of the capacitor relates to the power supply port;
a pre-set resistance device, coupled in parallel with the capacitor, for pre-setting an operating voltage of said circuit to make said circuit operate normally; and
a detecting device having an input coupled to the second terminal of the capacitor, once said transient voltage occurs at the power supply port, and when the voltage at the second terminal of the capacitor is higher than a threshold voltage, the detecting device outputting an output voltage for representing the occurrence of said transient voltage.

2. The circuit of claim 1, wherein the rectifying device consists of a plurality of diodes coupled in serial or a plurality of MOS transistors coupled in serial.

3. The circuit of claim 1, wherein the pre-set resistance device is a programmable resistor or a MOS transistor.

4. The circuit of claim 1, wherein the detecting device is an inverter or a comparator.

5. A circuit for detecting a transient voltage for an electronic system having a power supply port and a ground port, said circuit comprising:
a capacitor having a first terminal, coupled to the ground port, and a second terminal;
a rectifying device having an operating forward orientation, the second terminal of the capacitor being coupled through the rectifying device to the power supply port, and the operating forward orientation of the rectifying device orienting toward the capacitor such that a voltage at the second terminal of the capacitor relates to the power supply port; a pre-set resistance device, coupled in parallel with the rectifying device, for pre-setting an operating voltage of said circuit to make said circuit operate normally; and
a detecting device having an input coupled to the second terminal of the capacitor, once said transient voltage occurs at the power supply port, and when the voltage at the second terminal of the capacitor is higher than a threshold voltage, the detecting device outputting an output voltage for representing the occurrence of said transient voltage.

6. The circuit of claim 5, wherein the rectifying device consists of a plurality of diodes coupled in serial or a plurality of MOS transistors coupled in serial.

7. The circuit of claim 5, wherein the pre-set resistance device is a programmable resistor or a MOS transistor.

8. The circuit of claim 5, wherein the detecting device is an inverter or a comparator.

9. A circuit for detecting a transient voltage for an electronic system having a power supply port and a ground port, said circuit comprising:
a capacitor having a first terminal, coupled to the power supply port, and a second terminal;
a rectifying device having an operating forward orientation, the second terminal of the capacitor being coupled through the rectifying device to the ground port, and the operating forward orientation of the rectifying device orienting toward the capacitor such that a voltage at the second terminal of the capacitor relates to the ground port;
a pre-set resistance device, coupled in parallel with the rectifying device, for pre-setting an operating voltage of said circuit to make said circuit operate normally; and
a detecting device having an input coupled to the second terminal of the capacitor, once said transient voltage occurs at the ground port, and when the voltage at the second terminal of the capacitor is higher than a threshold voltage, the detecting device outputting an output voltage for representing the occurrence of said transient voltage.

10. The circuit of claim 9, wherein the rectifying device consists of a plurality of diodes coupled in serial or a plurality of MOS transistors coupled in serial.

11. The circuit of claim 9, wherein the pre-set resistance device is a programmable resistor or a MOS transistor.

12. The circuit of claim 9, wherein the detecting device is an inverter or a comparator.

13. A circuit for detecting a transient voltage for an electronic system having a power supply port and a ground port, said circuit comprising:
a capacitor having a first terminal, coupled to the power supply port, and a second terminal;
a rectifying device having an operating forward orientation, the second terminal of the capacitor being coupled through the rectifying device to the ground port, and the operating forward orientation of the rectifying device orienting toward the capacitor such that a voltage at the second terminal of the capacitor relates to the ground port;
a pre-set resistance device, coupled in parallel with the capacitor, for pre-setting an operating voltage of said circuit to make said circuit operate normally; and
a detecting device having an input coupled to the second terminal of the capacitor, once said transient voltage occurs at the ground port, and when the voltage at the second terminal of the capacitor is higher than a threshold voltage, the detecting device outputting an output voltage for representing the occurrence of said transient voltage.

14. The circuit of claim 13, the rectifying device consists of a plurality of diodes coupled in serial or a plurality of MOS transistors coupled in serial.

15. The circuit of claim 13, wherein the pre-set resistance device is a programmable resistor or a MOS transistor.

16. The circuit of claim 13, wherein the detecting device is an inverter or a comparator.
